(19) United States
(12) Patent Application Publication
(10) Pub. No.: US 2017/0214313 A1
(43) Pub. Date: Jul. 27, 2017

(54) DRIVE CIRCUIT FOR SEMICONDUCTOR SWITCHING ELEMENT

(71) Applicant: CALSONIC KANSEI CORPORATION, Saitama-shi, Saitama (JP)

(72) Inventor: Yoshiyuki KIKUCHI, Saitama-shi, Saitama (JP)

(73) Assignee: CALSONIC KANSEI CORPORATION, Saitama-shi, Saitama (JP)

(21) Appl. No.: 15/313,641

(22) PCT Filed: May 27, 2015
(86) PCT No.: PCT/JP2015/065284

§ 371 Date: Nov. 23, 2016

(30) Foreign Application Priority Data
May 29, 2014 (JP) 2014-111094

(51) Int. Cl. H02M 1/32; B60L 11/18; H03K 17/08; H03K 17/60; H02M 5/293; H02P 27/16

(52) U.S. Cl. CPC H02M 1/32; H02M 5/293; H02P 27/16; H03K 17/08; H03K 17/60; B60L 11/1803; H02M 2005/2932; B60Y 2200/91

(57) ABSTRACT

A drive circuit for a semiconductor switching element includes an overcurrent protection circuit, a short-circuit protection circuit, and a determination time changing circuit. The overcurrent protection circuit judges that a principal current become an overcurrent when a sense voltage proportional to magnitude of the principal current excesses over a first threshold value, and then reduces the principal current. The short-circuit protection circuit reduces a gate voltage of the semiconductor switching element more quickly than the reduction of the principal current by the overcurrent protection circuit when the principal current becomes a greater overcurrent. The determination time changing circuit makes a determination time needed for determining whether or not to operate the overcurrent protection circuit longer when the magnitude of the principal current gets smaller based on a comparison result between the judgement result of the overcurrent protection circuit and a second threshold value.

### TECHNICAL FIELD

The present invention relates to a drive circuit for a semiconductor switching element.

### BACKGROUND ART

A drive circuit for a semiconductor switching element is used for overcurrent protection of a switching circuit. In a drive circuit for a semiconductor switching element, two threshold values are provided in association with an overcurrent state in which a current over a maximum rated current flows and a short-circuit state in which a larger current flows at a short-circuit fault or the like, and the drive circuit for a semiconductor switching element operates differently according to the threshold values.

A drive circuit for a semiconductor switching element includes a configuration for avoiding breakdown of the semiconductor switching element. By this configuration, in the short-circuit state, a level of a gate voltage is reduced by a simple feedback circuit (short-circuit protection circuit) and then the level of the gate voltage is completely reduced to zero by an overcurrent protection circuit, in order to operate at higher speed than in the overcurrent state. A current value monitored by the overcurrent protection circuit is the same as a current value monitored by the short-circuit protection circuit, but the threshold value for the current value monitored by the overcurrent protection circuit is lower. Therefore, the overcurrent protection circuit has a higher possibility of malfunction caused by noises than the short-circuit protection circuit has. In the overcurrent protection circuit, noises are removed by setting a so-called masking time by a delay circuit in order to prevent malfunction (see a Patent Document 1 listed below).

### PRIOR ART DOCUMENT

### Patent Documents

Patent Document 1: Japanese Patent Application Publication No. 2012-231407

### SUMMARY OF INVENTION

In the above-mentioned prior-art drive circuit for a semiconductor switching element, a current value restricted in a short-circuit state varies according to deviations of characteristic of the semiconductor switching element. On the other hand, one of reasons for breakdown of a semiconductor switching element caused by a short-circuit is excessive temperature due to consumption energy in the semiconductor switching element. The consumption energy is determined from a short-circuit current and an integral value of time.

Costs of a semiconductor switching element used as a power semiconductor is roughly proportionate to its area. In view of this, downsizing of a semiconductor switching element is desired, but energy needed for breakdown becomes small when it is downsized and thereby margin for protection against a short-circuit gets reduced. Therefore, protection against a short-circuit is needed to be improved for downsizing. In this regard, if a short-circuit time is merely shortened, margin for protection against the above-mentioned malfunction gets reduced. Eventually, they have a tradeoff relationship.

Namely, although there is a little time to spare while a semiconductor switching element is led to breakdown in a case where a current flowing through it is small, a given length of time (determination time) elapses from a time when the current gets to be restricted to a time when the semiconductor switching element is completely turned off and then a short-circuit protection is finished. Although noise removal characteristic can be improved by expanding this determination time, the time to spare while the semiconductor switching element is led to breakdown cannot be utilized sufficiently at present.

An object of the present invention is to provide a drive circuit for a semiconductor switching element that can prevent malfunction caused by noises by expanding a determination time without breakdown of the semiconductor switching element.

An aspect of the present invention provides a drive circuit for a semiconductor switching element comprising: a semiconductor switching element that flows a principal current between a first terminal and a second terminal by applying a gate voltage to a gate terminal; an overcurrent protection circuit that judges that an overcurrent in which the principal current excesses over a given current value during a given time period occurs when an current value or a voltage value proportional to magnitude of the principal current excesses over a first threshold value, and then reduces the principal current; a short-circuit protection circuit that reduces the gate voltage more quickly than the reduction of the principal current by the overcurrent protection circuit when the principal current becomes a greater overcurrent than the overcurrent during a shorter time period than the given time period; and a determination time changing circuit that makes a determination time needed for determining whether or not to operate the overcurrent protection circuit longer when the magnitude of the principal current gets smaller based on a comparison result between the judgement result of the overcurrent protection circuit and a second threshold value.

### BRIEF DESCRIPTION OF DRAWINGS

FIG. 1 It is a circuit diagram of a drive circuit for a semiconductor switching element according to a first embodiment.

FIG. 2 It shows waveform diagrams for explaining operations of the semiconductor switching element according to the first embodiment.

FIG. 3 It is a circuit diagram of a general drive circuit for a semiconductor switching element.

FIG. 4 It shows waveform diagrams for explaining operations of the general drive circuit for a semiconductor switching element.

FIG. 5 It is a circuit diagram of a drive circuit for a semiconductor switching element according to a second embodiment.

### DESCRIPTION OF EMBODIMENTS

A drive circuit for a semiconductor switching element according to embodiments will be described with reference to the drawings.

### First Embodiment

A drive circuit for a semiconductor switching element according to the present embodiment is used for supplying electric power to each of coils in a motor (e.g. three-phase AC motor) installed on an electric vehicle. The drive circuit for a semiconductor switching element includes a main circuit MC that includes part of coils of the motor and part of an inverter circuit, a short-circuit protection circuit SP, and an overcurrent protection circuit OP that is comprised of a threshold value setting circuit TC that sets a voltage threshold value of an overcurrent and a switching circuit SC.

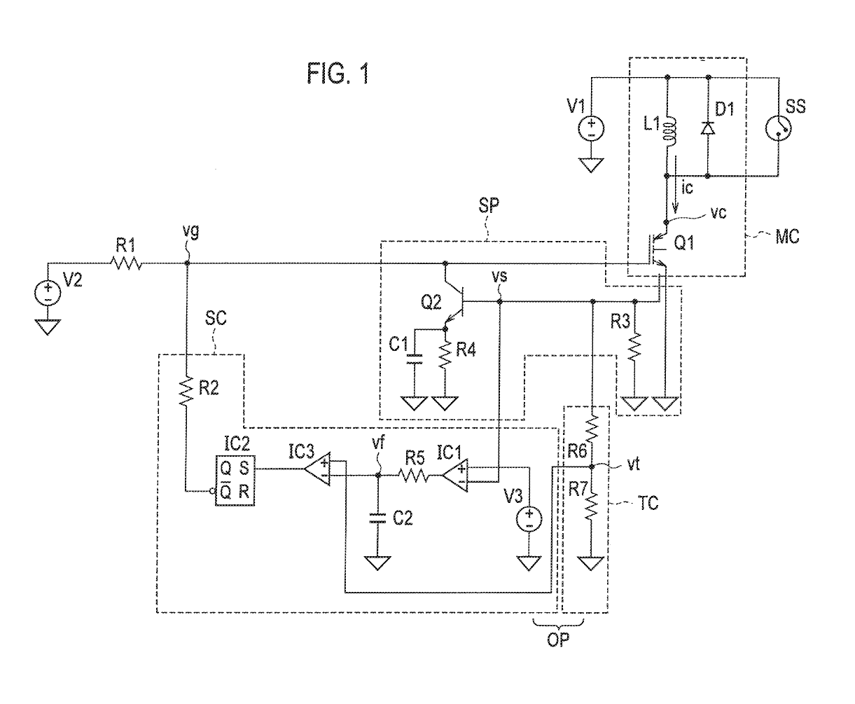

Note that the main circuit MC shown in FIG. 1 includes part of coils of a motor and part of an inverter circuit for simulation.

The main circuit MC includes a coil L1 of a motor, a feedback diode D1 connected parallel to the coil L1, and an Insulated Gate Bipolar Transistor (IGBT) Q1 that serves as a semiconductor switching element.

Electric power is supplied to the coli L1 from a power source V1. Note that, in the drive circuit for the semiconductor switching element shown in FIG. 1, a short-circuit switch SS that short-circuits both ends of the coil L1 and the feedback diode D1 provided parallel to each other in order to investigate its characteristic. The short-circuit switch SS is not needed in a case of applying the drive circuit for the semiconductor switching element to an actual electric vehicle.

Terminals of the coil L1 and the feedback diode D1 on an opposite side to the power source V1 are connected to a collector terminal of the IGBT Q1. An emitter terminal of the IGBT Q1 is earthed. Agate terminal of the IGBT Q1 is connected to a power source V2 via a gate resistor R1. When a voltage more than a given value is applied to the gate terminal, the IGBT Q1 flows a collector current (principal current) ic depending on the voltage from its collector terminal to its emitter terminal. Due to this operation, a current supplied to the coil L1 of the motor is controlled. Note that one of the collector terminal and the emitter terminal of the IGBT Q1 corresponds to a first terminal, and the other of them corresponds to a second terminal.

The short-circuit protection circuit SP includes a transistor Q2 for restricting overcurrent, a resistor R3, a resistor R4, and a capacitor C1. A collector terminal of the transistor Q2 is connected to a connection point between the gate terminal of the IGBT Q1 and the resistor R1. An emitter terminal of the transistor Q2 is earthed via the capacitor C1 and the resistor R4 that are provided parallel to each other. A sense terminal of the transistor Q2 is connected to a sense terminal of the IGBT Q1. The sense terminal of the IGBT Q1 is a current detection terminal to which a current proportional to the collector current ic flows.

A connection point between the sense terminal of the IGBT Q1 and the base terminal of the transistor Q2 is earthed via the resistor R3. This connection point is connected further to an inverting input terminal of a comparator IC1 of the switching circuit SC and a resistor R6 of the threshold value setting circuit TC. A resistor R2 of the switching circuit SC is connected to a connection point between the collector terminal of the transistor Q2 and the gate resistor R1. Note that a gate voltage vg is generated at the connection point between the gate resistor R1 and the gate terminal of the IGBT Q1. In addition, a sense voltage vs is generated at a connection point between the sense terminal of the IGBT Q1 and the base terminal of the transistor Q2.

The threshold value setting circuit TC in the overcurrent protection circuit OP corresponds to a threshold changing circuit, and is comprised of resistors R6 and R7 that are connected sequentially with each other. The base terminal of the transistor Q2 and the sense terminal of the IGBT Q1 are earthed via the resistors R6 and R7. An overcurrent threshold voltage vt that is obtained by dividing the sense voltage vs by the resistors R6 and R7 is applied to a non-inverting input terminal of a comparator IC3 of the switching circuit SC.

The switching circuit SC in the overcurrent protection circuit OP has functions of noise removing, delaying and latching, and is used to turn the IBGT Q1 off by reducing the gate voltage vg. The switching circuit SC includes a power source V3, the comparator IC1, the comparator IC3, the resistor R2, a resistor R5, a capacitor C2, and a SR flip-flop IC2. The comparator IC3 corresponds to a determination time changing circuit.

A reference voltage from the power source V3 is input to a non-inverting input terminal of the comparator IC1. The sense voltage vs is input to the inverting input terminal of the comparator IC1. The comparator IC1 outputs an L-level (0 volt) signal from its output terminal when the sense voltage vs excesses over the reference voltage from the power source V3, or outputs an H-level signal from its output terminal when it doesn't. The output of the comparator IC1 is input to an inverting input terminal of the comparator IC3 via the resistor R5.

A connection point between the inverting input terminal of the comparator IC3 and the resistor R5 is earthed via the capacitor C2. A circuit constituted by the resistor R5 and the capacitor C2 also functions as a low-pass filter that removes high-frequency noises. A filter voltage vf is generated at a connection point between the inverting input terminal of the comparator IC3 and the resistor R5.

The comparator IC3 outputs an L-level (0 volt) determination signal from its output terminal when the filter voltage vf excesses over the overcurrent threshold voltage vt from the threshold value setting circuit TC, or outputs an H-level determination signal from its output terminal when it doesn't. The output of the comparator IC3 is input to a set terminal (S terminal) of the SR flip-flop IC2 as a latch circuit.

An inverting output terminal (Q̅) is connected to the connection point between the gate resistor R1 and the IGBT Q1 via the resistor R2. The SR flip-flop IC2 is set when the determination signal from the comparator IC3 is not less than a preset level (a threshold value of the SR flip-flop IC2), and outputs an L-level signal from the inverting output terminal (Q̅). On the other hand, it maintains its previous state when the determination signal from the comparator IC3 is less than the preset level. Namely, in a case where an initial state is a state where the SR flip-flop IC2 is reset, an H-level signal is output from the inverting output terminal (Q̅).

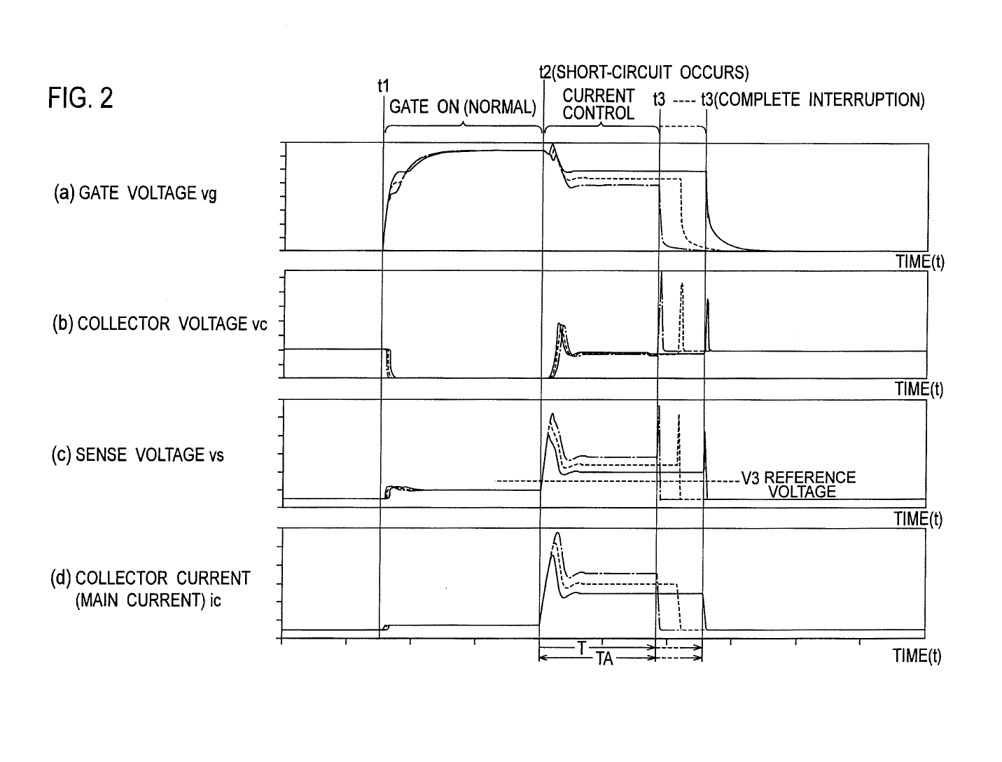

Next, operations of the above-described drive circuit for the semiconductor switching element will be described with reference to waveform diagrams shown in FIG. 2(a) to FIG. 2(d). FIG. 2(a) shows the gate voltage vg, FIG. 2(b) shows the collector voltage vc, FIG. 2(c) shows the sense voltage vs, FIG. 2(d) shows a current flowing through the main circuit (from the coil L1 to the IGBT Q1), i.e. the collector current ic of the IGBT Q1.

FIG. 2(a) to FIG. 2(d) show a simulation result in a case where a short-circuit occurs (the short-circuit switch SS is closed). The IGBT Q1 is turned on at a time t1, an arm short-circuit at the inverter, a short-circuit in the motor or the like occurs at a time t2, and voltage application to the gate terminal of the IGBT Q1 is stopped (complete interruption) at a time t3 after an overcurrent is detected. Note that the overcurrent generation is detected based on the sense voltage vs, but the sense voltage vs increases instantaneously as shown in FIG. 2(c). Therefore, in following descriptions, it is regarded that the overcurrent is detected at the time t2.

Note that a time period from a time when the overload is detected (time t2) by the resistor R3 of the short-circuit protection circuit SP to a time when the overload protection circuit OP operates (time t3) after a delay time T elapses, is called a time period TA. In addition, in FIG. 2(a) to FIG. 2(d), three types of characteristics are shown according to variations of the threshold voltage of the IGBT Q1: one with a low threshold voltage is shown by a dashed-dotted line, one with a middle threshold voltage is shown by a dotted line, and one with a high threshold voltage is shown by a solid line. Further, in FIG. 2(a) to FIG. 2(d), a position of the time t3 varies according to the threshold voltage of the IBGT Q1.

At the time ti, the IGBT Q1 is turned on and thereby a power supply to the coil L1 in the motor is started. In a case of a normal drive state of the motor where a short-circuit and an overcurrent don't occur (gate-on state), as already known, a current between the collector terminal and the emitter terminal, i.e. the principal current ic flowing through the coil in the motor is changed by controlling a pulse width of the gate voltage vg of the IGBT Q1 by a control circuit (not shown in the drawings) to get a required drive force of the motor.

At the gate-on, as shown in FIG. 2(a), the gate voltage vg rises immediately at the time t1 and then maintains an almost constant value. As shown in FIG. 2(d), due to the rise of the gate voltage vg, the collector current ic flows from the collector to the emitter of the IGBT Q1. Since the sense current proportional to the collector current ic flows concurrently, also the sense voltage vs of the IGBT Q1 that is determined by the sense current and the resistor R3 rises and then maintains an almost constant value.

In addition, the reference voltage input from the power source V3 to the non-inverting input terminal of the comparator IC1 of the switching circuit SC, is set so as to be higher at the gate-on than the sense voltage vs input to the inverting input terminal of the comparator IC1. Therefore, the comparator IC1 outputs an H-level signal at the gate-on. As the result, the filter voltage vf at the connection point between the resistor R5 and the non-inverting input terminal of the comparator IC3 maintains its maximum value.

On the other hand, the overcurrent threshold voltage vt of the threshold value setting circuit TC rises at the time t1 at which the sense voltage vs is generated, and then keeps a voltage (R7·vs/(R6+R7)) that is obtained by dividing the sense voltage vs by the resistors R6 and R7. Here, the above-mentioned filter voltage vf that is input from the comparator IC1 to the inverting input terminal of the comparator IC3 of the switching circuit SC via the resistor R5, is higher than the overcurrent threshold voltage vt that is input to the non-inverting input terminal. Therefore, the comparator IC3 outputs an L-level signal. As the result, the switching circuit SC of the overcurrent protection circuit OP doesn't operate, and thereby the gate terminal of the IGBT Q1 remains ungrounded.

In addition, although the sense voltage vs is applied also to the base terminal of the transistor Q2, its value is small and lower than the threshold voltage of the transistor Q2. Therefore, the transistor Q2 maintains its OFF state in which its collector and its emitter are disconnected from each other, and thereby the short-circuit protection circuit SP doesn't operate. As the result, the gate terminal of the IGBT Q1 is not earthed via the capacitor C1 and the resistor R4, and the power supply to the coil L1 is maintained to drive the motor.

Note that, before the IGBT Q1 is turned on, the collector current ic doesn't flow through the IGBT Q1. However, as shown in FIG. 2(b), the IGBT Q1 primitively has a configuration that sets its collector-side voltage higher than its emitter-side voltage, so that the collector voltage vc indicates a value caused by this configuration. But, when the gate voltage vg is applied to the IGBT Q1 at the time t1 and the collector current ic depending on the gate voltage vg flows between the collector and the emitter, the collector current ic rises and then maintains a given value as shown in FIG. 2(d). When the collector current ic flows through the emitter (when being biased in a forward direction), the collector voltage vc reduces to its ON voltage (almost a few volts).

It is assumed that an arm short-circuit occurs at the time t2 at the above-described gate-on, for example. When the short-circuit switch SS of the main circuit MC is closed in order to simulate this short-circuit, the collector current ic increases instantaneously at the time t2 as shown in FIG. 2(d) and then overcurrent occurs. Here, the sense voltage vs also rises instantaneously as shown in FIG. 2(c), and then the short-circuit protection circuit SP operates. Namely, the sense voltage vs that gets higher than the threshold voltage of the transistor Q2 according to the overcurrent is applied to the base terminal of the transistor Q2, and thereby the transistor Q2 is turned on to flow a current. As the result, a current being input to the gate terminal of the IGBT Q1 flows to the ground via the transistor Q2 and the resistor R4. Therefore, as shown in FIG. 2(a), the gate voltage vg reduces to a given voltage value that balances the gate voltage vg and the sense voltage vs. As shown in FIG. 2(d), along with the reduction of the gate voltage vg, the collector current ic also reduces. The gate voltage vg is controlled in this manner, so that the collector current ic is restricted from increasing to restrict breakdown of the IGBT Q1.

Note that, since the capacitor C1 is connected parallel to the resistor R4 between the emitter terminal of the transistor Q2 and the ground as described above, high-frequency component of the gate voltage vg is released to the ground quickly. In addition, stabilization of the gate voltage vg to the given voltage value is done by the resistor R4. Therefore, the short-circuit protection circuit SP restricts the gate voltage vg immediately when a short-circuit occurs.

During the above-mentioned time period TA, the lower the threshold voltage of the IGBT Q1 is, the lower the gate voltage vg during under operations of the short-circuit protection circuit SP is. In this case, differently from a time period prior to the time t2, the gate voltage vg changes significantly (varies significantly) according to the threshold voltage vth.

On the other hand, the overcurrent threshold voltage vt is obtained by dividing the sense voltage vs by the resistors R6 and R7, and is proportional to the sense voltage vs. Therefore, during the time period TA, the lower the sense voltage vs is, the lower the overcurrent threshold voltage vt is. In this case, the lower the threshold voltage is, the higher the overcurrent threshold voltage vt is. The overcurrent threshold voltage vt also changes significantly (varies significantly) according to the threshold voltage.

The overcurrent threshold voltage vt is input to the non-inverting input terminal of the comparator IC3, and then compared with the filter voltage vf that is input from the comparator IC1 to the inverting input terminal of the comparator IC3 via the resistor R5. As shown in FIG. 2(d), during the time period TA, the collector current ic maintains an almost constant value after its reduction along with the reduction of the gate voltage vg. This constant value is larger than the constant current ic between the time t1 and t2. Here, the lower the threshold voltage of the IGBT Q1 is, the larger a maximum value of the collector current ic after the time t2 is. In addition, the lower the threshold voltage of the IGBT Q1 is, the larger the above-mentioned constant value of the collector current ic is. The maximum value and the constant value change significantly (vary significantly) according to the threshold voltage. Note that, as shown in FIG. 2(b), during the time period TA, the collector voltage vc rises to a value equivalent to that during the gate-off prior to the time t1 along with the reduction of the gate voltage vg (by being balanced with the gate voltage vg).

As shown in FIG. 2(c), during the time period TA, the reference voltage of the power source V3 is set so as to be smaller than the constant value of the sense voltage vs. Therefore, the comparator IC1 outputs an L-level signal when an overcurrent occurs, and the L-level signal is input to the inverting input terminal of the comparator IC3 and the capacitor C2 via the resistor R5. Since the capacitor C2 is gradually discharged by the L-level signal output from the comparator IC1, the filter voltage of gradually reduces and then gets smaller than the overcurrent threshold voltage vt at the time t3 after the delay time (so-called masking time) T elapses from the time t2 (T=t3−t2). As the result, the comparator IC3 outputs an H-level determination signal, and then the H-level determination signal is input to a set input terminal (S terminal) of the SR flip-flop IC2 (H-level voltage is applied).

When the H-level voltage is applied to the set input terminal (S terminal) of the SR flip-flop IC2 at the time t3, an L-level (0 volt) signal (voltage) is output from the inverting output terminal (Q̅). A point between the resistor R1 and the gate terminal of the IGBT Q1 is earthed by this signal (voltage), and thereby the gate voltage vg reduces until the IGBT Q1 is turned off. As the result, the IGBT Q1 is forcibly made into the OFF state and the collector current ic also becomes 0 ampere, and thereby the IGBT Q1 is protected from its breakdown caused by the overcurrent.

Since the sense voltage vs reduces after the time t3 and the comparator IC1 outputs the H-level signal, the capacitor C2 is recharged. As the result, the filter voltage vf gradually increases, and thereby an L-level determination signal is input to the set input terminal (S terminal) of the SR flip-flop IC2 (L-level voltage is applied). However, the SR flip-flop IC2 functions as a latch circuit to maintain a prior state, and thereby the gate voltage vg doesn't rise again.

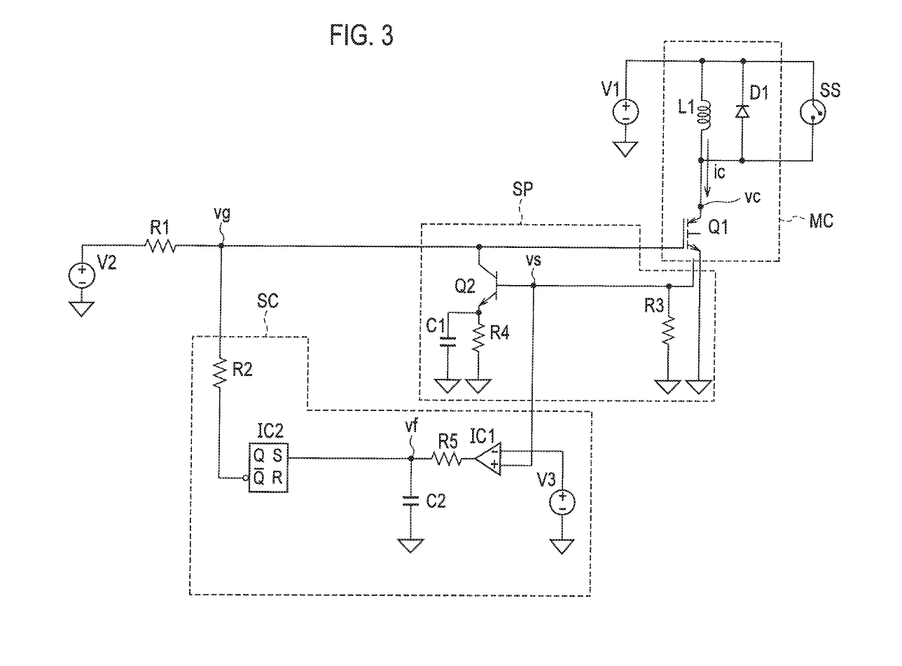

Next, advantages of the drive circuit for the semiconductor switching element according to the first embodiment will be explained in comparison with a general drive circuit for a semiconductor switching element shown in FIG. 3. In the general drive circuit for a semiconductor switching element, the threshold value setting circuit TC and the comparator IC3 of the switching circuit SC are removed from the above-described first embodiment, and an output of the comparator IC1 is directly input to the set input terminal (S terminal) of the SR flip-flop IC2 via the resistor R5.

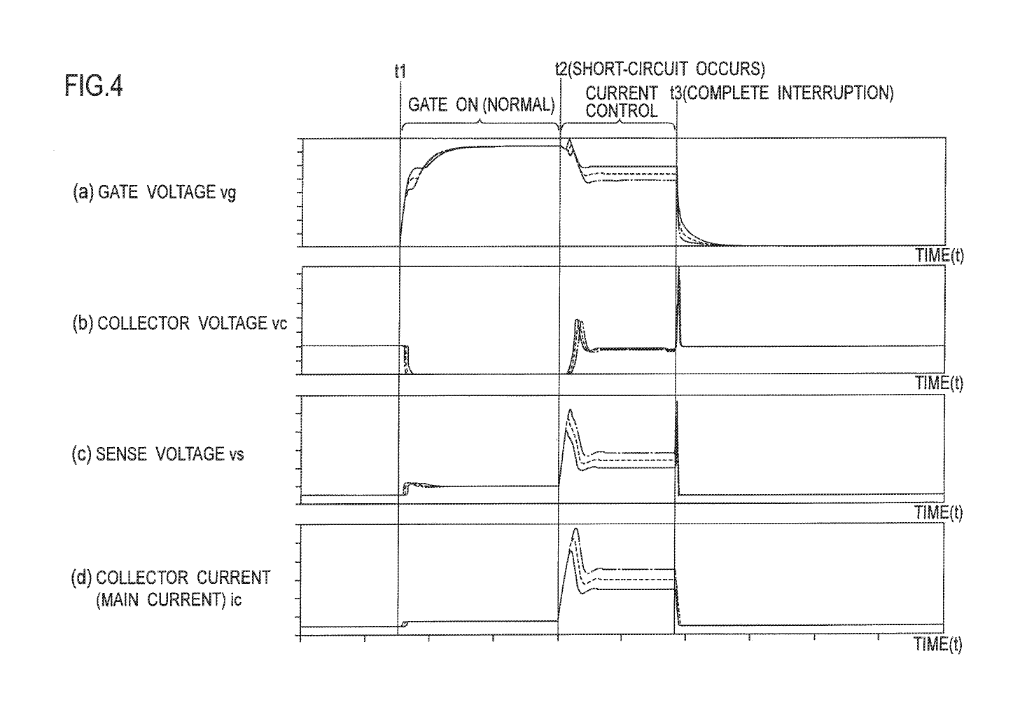

Operations of the general drive circuit for a semiconductor switching element will be described with reference to waveform diagrams shown in FIG. 4(a) to FIG. 4(d).

A short-circuit occurs at the time t2, an overcurrent flowing through the IGBT Q1 is detected by the resistor R3, and the transistor Q2 is turned on to flow a current. The current that is input to the gate terminal of the IGBT Q1 flows to the ground via the transistor Q2 and the resistor R4. Therefore, as shown in FIG. 4(a), the gate voltage vg reduces to a given voltage value that balances the gate current vg and the sense voltage vs. As shown in FIG. 4(d), along with the reduction of the gate voltage vg, the collector current ic also reduces. The gate voltage vg is controlled in this manner, so that the collector current ic is restricted from increasing to restrict breakdown of the IGBT Q1.

The restriction state of the collector current ic is detected by the comparator IC1, and the SR flip-flop IC2 is set when a determination time that is generated by the capacitor C2 and a threshold value of the set terminal (S terminal) of the flip-flop IC2 has elapsed. As the result, an L-level (0 volt) signal (voltage) is output from the inverting output terminal (Q̅) of the SR flip-flop IC2. A point between the resistor R1 and the gate terminal of the IGBT Q1 is earthed by this signal (voltage), and thereby the gate voltage vg reduces until the IGBT Q1 is turned off at the time t3. As the result, the IGBT Q1 is completely made into the OFF state and the collector current ic also becomes 0 as shown in FIG. 4(d), and thereby the IGBT Q1 is protected from its breakdown caused by the overcurrent. The above-mentioned determination time is provided in order to avoid malfunction caused by various noises in the circuits.

In the above-described general drive circuit for the semiconductor switching element, the determination time is made fixed so that it has been adjusted to be a time that prevents breakdown of the IGBT Q1 even if the collector current ic gets large due to deviations of characteristic of the IGBT Q1.

On the other hand, in the drive circuit for the semiconductor switching element according to the first embodiment, a current flowing through the IGBT Q1 is detected by the resistor R3, and the sense voltage vs depending on the current detected by the resistor R3 is output. The comparator IC3 prolongs a length of the determination time needed for determining whether or not to operate the overcurrent protection circuit in a case where the collector current ic is small, based on the comparison result between the overcurrent threshold voltage vt and the judgement results of the overcurrent protection judgement done by the comparator IC1. Namely, the length of the determination time is adjusted according to the sense voltage vs.

As shown in FIG. 2(d), when the IGBT Q1 suffers little strain, i.e. when the collector current ic flowing through the IGBT Q1 is small, the determination time is extended. As the result, the determination time can be extended without breakdown of the IGBT Q1, and thereby malfunction caused by noises can be prevented.

### Second Embodiment

In the first embodiment, the determination time is adjusted by the sense voltage vs. On the other hand, the determination time is adjusted by the gate voltage vg in the present embodiment. Note that, in following descriptions, configurations identical or equivalent to those in the first embodiment are labelled with identical signs, and their detailed explanations will be omitted.

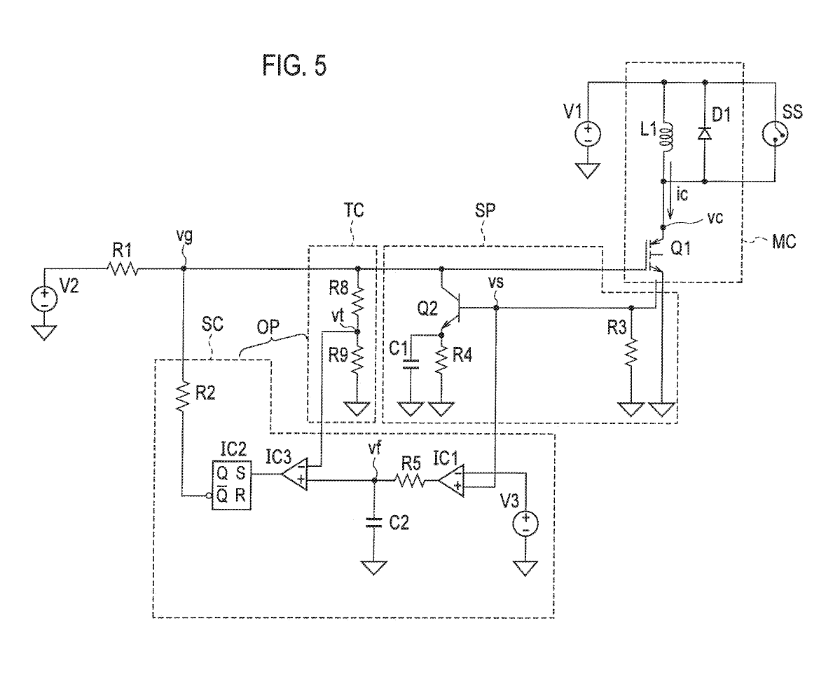

In the first embodiment, the threshold value setting circuit TC divides the sense voltage vs by the resistors R6 and R7 to generate the overcurrent threshold voltage vt. In the present embodiment, as shown in FIG. 5, the resistors R6 and R7 are removed and the overcurrent threshold voltage vt is generated by dividing the gate voltage vg by resistors R8 and R9. Note that waveform diagrams in the present embodiment are the same as the waveform diagrams shown in FIG. 4(a) to FIG. 4(d).

The overcurrent threshold voltage vt of the threshold value setting circuit TC is a voltage (R9·vg/(R8+R9)) that is obtained by dividing the gate voltage vg by the resistors R8 and R9, and thereby it is proportional to the gate voltage vg. The overcurrent threshold voltage vt is input to the inverting input terminal of the comparator IC3 of the switching circuit SC, and then compared with the filter voltage of that is input from the comparator IC1 to the non-inverting input terminal of the comparator IC3 via the resistor R5.

In the drive circuit for the semiconductor switching element according to the present embodiment, the current flowing through the IGBT Q1 is changed and the determination time is adjusted variably according to the gate voltage vg during the current restriction. Specifically, when the IGBT Q1 suffers little strain, i.e. when the collector current ic flowing through the IGBT Q1 is small, the determination time is extended. As the result, the determination time can be extended without breakdown of the IGBT Q1, and thereby malfunction caused by noises can be prevented.

In the first and second embodiments, the drive circuit for the semiconductor switching element comprises: the semiconductor switching element (the IGBT Q1) that flows the principal current (the collector current ic) between the first terminal and the second terminal (the collector terminal and the emitter terminal) by applying the gate voltage (vg) to the gate terminal; the overcurrent protection circuit (OP) that judges that an overcurrent in which the principal current excesses over a given current value during a given time period (the comparator IC1 outputs an L-level signal) occurs when an current value or a voltage value proportional to magnitude of the principal current (the sense voltage vs) excesses over a first threshold value (the reference voltage of the power source V3) (vs>reference voltage: the comparator IC1), and then reduces the principal current; the short-circuit protection circuit (SP) that reduces the gate voltage (vg) more quickly (the gate voltage vg is earthed via the transistor Q2 and the resistor R4) than the reduction of the principal current by the overcurrent protection circuit (OP) when the principal current becomes a greater overcurrent (short-circuit: the sense voltage vs>the threshold voltage of the transistor Q2) than the overcurrent during a shorter time period than the given time period; and the determination time changing circuit (the comparator IC3 and the capacitor C2) that makes the determination time needed for determining whether or not to operate the overcurrent protection circuit (OP) longer when the magnitude of the principal current gets smaller based on the comparison result (the comparator IC3) between the judgement result of the overcurrent protection circuit (OP) and a second threshold value (the overcurrent threshold voltage vt).

Here, in the first embodiment, the determination time changing circuit (the comparator IC3) determines the magnitude of the principal current based on the sense voltage (vs) of the semiconductor switching element (the IBGT Q1) (determines it by comparing the overcurrent threshold voltage vt proportional to the sense voltage vs with the filter voltage vf). In addition, the drive circuit for the semiconductor switching element further comprises the threshold value changing circuit (TC) that changes the second threshold value (the overcurrent threshold voltage vt) in proportion to the sense voltage (vs) (vt=R7·vs/(R6+R7)).

On the other hand, the determination time changing circuit (the comparator IC3) determines the magnitude of the principal current based on the gate voltage (vg) (determines it by comparing the overcurrent threshold voltage vt proportional to the gate voltage vg with the filter voltage vf). In addition, the drive circuit for the semiconductor switching element further comprises the threshold value changing circuit (TC) that changes the second threshold value (the overcurrent threshold voltage vt) in proportion to the gate voltage (vg) (vt=R9·vg/(R8+R9)).

1.-5. (canceled)

6. A drive circuit for a semiconductor switching element comprises:
a semiconductor switching element that flows a principal current between a first terminal and a second terminal by applying a gate voltage to a gate terminal;
an overcurrent protection circuit that judges that an overcurrent in which the principal current excesses over a given current value during a given time period occurs when an current value or a voltage value proportional to magnitude of the principal current excesses over a first threshold value, and then reduces the principal current;
a short-circuit protection circuit that reduces the gate voltage more quickly than the reduction of the principal current by the overcurrent protection circuit when the principal current becomes a greater overcurrent than the overcurrent during a shorter time period than the given time period; and
a determination time changing circuit that makes a determination time needed for determining whether or not to operate the overcurrent protection circuit longer when the magnitude of the principal current gets smaller based on a comparison result between the judgement result of the overcurrent protection circuit and a second threshold value, wherein
the determination time changing circuit determines the magnitude of the principal current based on the gate voltage.

7. The drive circuit for a semiconductor switching element according to claim 6, further comprising
a threshold value changing circuit that changes the second threshold value in proportion to the gate voltage.
